(19) United States
(12) Patent Application Publication
(10) Pub. No.: US 2011/0057712 A1
(43) Pub. Date: Mar. 10, 2011

(54) SELF-HEALING TECHNIQUE FOR HIGH FREQUENCY CIRCUITS

(75) Inventors: Steven Bowers, Duarte, CA (US); Kaushik Sengupta, Pasadena, CA (US); Seyed Ali Hajimiri, Pasadena, CA (US)

(73) Assignee: California Institute of Technology, Pasadena, CA (US)

(21) Appl. No.: 12/877,743

(22) Filed: Sep. 8, 2010

Related U.S. Application Data
(60) Provisional application No. 61/240,518, filed on Sep. 8, 2009.

(51) Int. Cl. H03K 17/56

(52) U.S. Cl. 327/419

(57) ABSTRACT

A self-healing monolithic integrated includes an electronic circuit having a plurality of transistors. At least one sensor is disposed within and electrically coupled to the electronic circuit and configured to sense a performance metric of the electronic circuit. A plurality of actuators is disposed within the circuit. Each actuator of the plurality of actuators has electrically coupled to it a control terminal. The plurality of actuators is configured to perform a selected one of, electrically coupling at least one transistor of the plurality of transistors into the electronic circuit and electrically de-coupling at least one transistor of the plurality of transistors, in response to operation of one of the control terminals to improve the performance metric.

### CROSS-REFERENCE TO RELATED APPLICATIONS

This application claims priority to and the benefit of co-pending U.S. provisional patent application Ser. No. 61/240,518, filed Sep. 8, 2009, entitled “Self Healing Technique for High Frequency Circuits,” which application is incorporated herein by reference in its entirety. Co-pending U.S. patent application Ser. No. 12/806,906, filed Aug. 24, 2010, entitled “ELECTRONIC SELF-HEALING METHODS FOR RADIO-FREQUENCY RECEIVERS,” and further identified by Attorney Docket Number CIT-5211, is a related application that is incorporated herein by reference in its entirety.

### FIELD OF THE INVENTION

The invention relates to integrated circuits in general and particularly to integrated circuits which employ circuit topologies that provide increased manufacturing yields.

### BACKGROUND OF THE INVENTION

In recent years, there has been increased activity in the development of mm-wave (millimeter wave) integrated circuits. There has also been an increased interest in systems on silicon, such as those related to monolithic integration in CMOS, as well as to relatively low cost related CMOS processes. This research has followed the aggressive scaling down of transistor size. In fact device fₘₐₓ/f_{T} has pushed high enough that CMOS processes can now be considered for a range of applications which had previously been completely dominated by the more exotic and expensive III-V compound semiconductor processes.

However, because of low manufacturing yields and the high economic costs of design and manufacture, integrating large numbers of transistors in silicon by use of existing process technologies remains problematic for high frequency circuits. Conservative designs, which have attempted to increase production yields by increasing design margins, have proven to be wasteful and inefficient solutions. Even more problematic are designs which include a RF power amplifier (PA), such as a high frequency (e.g. mm-wave) PA.

What is needed, therefore, is a new cost effective architecture which can increase high frequency integrated circuit production yields.

### SUMMARY OF THE INVENTION

In one aspect, the invention relates to a self-healing monolithic integrated which includes an electronic circuit having a plurality of transistors. The electronic circuit is disposed between and electrically coupled to at least one input terminal and at least one output terminal. At least one sensor is disposed within and electrically coupled to the electronic circuit and configured to sense a performance metric of the electronic circuit. A plurality of actuators is disposed within the circuit. Each actuator of the plurality of actuators has electrically coupled to it a control terminal. The plurality of actuators is configured to perform a selected one of, electrically coupling at least one transistor of the plurality of transistors into the electronic circuit and electrically de-coupling at least one transistor of the plurality of transistors, in response to operation of one of the control terminals to improve the performance metric. At least one power terminal and at least one common terminal are electrically coupled to the electronic circuit and configured to accept power to operate the self-healing monolithic integrated circuit.

In one embodiment, the self-healing monolithic integrated circuit includes a CMOS technology.

In another embodiment, the performance metric includes a performance metric selected from the group consisting of output power, efficiency, gain, PAE, and linearity.

In yet another embodiment, the self-healing monolithic integrated circuit is a component of a system selected from the group of systems consisting of a point-to-point link, a local area network (LAN), a personal area network (PAN), a vehicle radar system, an all weather vision system, a medical imaging sensor, a space probe imaging system, and a plasma diagnostic system.

In yet another embodiment, the self-healing monolithic integrated circuit further includes a general purpose programmable computer and a set of instructions recorded on a computer-readable medium which when operating on the general purpose programmable computer cause the general purpose programmable computer to be configured to receive sensed information and to set at least one of the control terminals to optimize the performance metric.

In yet another embodiment, the set of instructions is recorded on a computer-readable medium and when operating runs on a computer device external to the monolithic integrated circuit.

In yet another embodiment, the set of instructions is recorded on a computer-readable medium and when operating runs on a digital circuit disposed within the monolithic integrated circuit.

In yet another embodiment, the digital circuit includes a state machine.

In yet another embodiment, the state machine is further controlled by a parent set of instructions recorded on a computer-readable medium.

In yet another embodiment, the actuator includes a tunable matching network.

In yet another embodiment, the tunable matching network includes a selected one of a T-line and a tunable slow-wave transmission line.

In yet another embodiment, the self-healing monolithic integrated circuit is configured to automatically self-heal in response a change in antenna impedance.

In yet another embodiment, the circuit includes a mm-wave circuit.

In yet another embodiment, the self-healing monolithic integrated circuit senses a phase difference between a gate current and a drain voltage.

In yet another embodiment, the self-healing monolithic integrated circuit is configured to operate at least one of the control terminals to cause the phase difference between the gate current and the drain voltage to change towards a quadrature phase difference.

In yet another embodiment, the self-healing monolithic integrated circuit is configured to adjust a bias voltage or a threshold voltage through body effect (triple-well process) based on a gain estimate based on an output of a peak detector sensor.

In yet another embodiment, the self-healing monolithic integrated circuit includes a Schottky peak detector.

In yet another embodiment, the self-healing monolithic integrated circuit senses an efficiency metric of the circuit using a temperature sensor.

In yet another embodiment, the temperature sensor includes a PTAT sensor.

In yet another embodiment, the self-healing monolithic integrated circuit further includes two or more on-chip antennas configured to provide power combining.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 shows a schematic diagram of an exemplary power amplifier.

FIG. 2A shows graph of a Monte Carlo simulation of wafer-to-wafer variation over a range of output power for the circuit of FIG. 1.

FIG. 2B shows graph of a Monte Carlo simulation of wafer-to-wafer variation simulation over a range of PAE for the circuit of FIG. 1.

FIG. 3 shows a block diagram of an exemplary simplified block diagram of a two stage power amplifier according to the invention.

FIG. 4A shows a schematic diagram of an exemplary tunable matching network using a T-line suitable for use in the power amplifier of FIG. 3.

FIG. 4B shows a perspective view of another exemplary tunable show-wave transmission line suitable for use in the power amplifier of FIG. 3.

FIG. 4C shows a schematic diagram which illustrates another exemplary actuator circuit topology suitable for use in the power amplifier of FIG. 3.

FIG. 5 shows a block diagram of one exemplary embodiment of a self healing power amplifier having eight parallel amplifier stages.

### DETAILED DESCRIPTION

### Definitions

As used in the present disclosure, we define the range of electromagnetic waves from microwave to “mm-wave” to correspond generally to a frequency range of about 10 to 300 GHz. The more general term of “high frequency” includes sub mm-wave as well as mm-wave frequencies. The self-healing techniques described herein are particularly advantageous in adapting semiconductor processes, such as for example, digital CMOS processes, to mm-wave operation. However, it is understood that the technologies described herein can also be applied generally to any similar circuits operating at any high frequency.

### Challenges in CMOS Fabrication

Some conventional CMOS fabrication processes, including digital CMOS fabrication processes, are not well suited for use at mm-wave frequencies. The lower mobility of CMOS devices as compared to III-V semiconductor devices, lower quality factor of passive components, and lossy silicon substrates all contribute to high ohmic losses, and pose challenges to silicon integration and efficient power generation at mm-wave frequencies. CMOS RF designs are further constrained by a proportional scaling in breakdown voltages which fundamentally limits the amount of power that can be obtained from a single transistor.

Some design methodologies for mm-wave silicon integration that scale with technology have been developed. For example in Komijani and Hajimiri, A 24 GHz, +14.5 dBm fully-integrated power amplifier in 0.18 μm CMOS, Custom Integrated Circuits Conference, 2004, Proceedings of the IEEE 2004, pages 561-564, October, 2004, a slow-wave structure was described, which effectively reduced substrate loss and on-chip wavelength and achieved a +14.5 dBm output power in 180 nm CMOS with a 3.1 GHz bandwidth at 24 GHz. A 77 GHz power amplifier was described by Komijani and Hajimiri in a wideband 77 GHz, 17.5 dBm power amplifier in silicon, Custom Integrated Circuits Conference, 2005, Proceedings of the IEEE 2005, pages 571-574, September, 2005, in which a 130 nm SiGe BiCMOS process yielded a device which achieved +17.5 dBm with a PAE (power added efficiency) of 12.8%.

A resonant impedance match using transmission lines or lumped passive components is inherently narrow-band and therefore sensitive to inaccuracies of active and passive modeling. An extremely wideband combining network was proposed and implemented using a non-uniform transmission line which funneled the output power of four stages into a load, achieving an output power of 125 mW at 84 GHz with a 3 dB bandwidth of 24 GHz in 130 nm SiGe BiCMOS technology. These technologies have been described in United States Patent Application Publication No. 2007/0086786, Electrical funnel: a novel broadband signal combining method, filed Sep. 22, 2006, and United States Patent Application Publication No. 2009/0096554, 2D TRANSMISSION LINE-BASED APPARATUS AND METHOD, filed Oct. 16, 2008, both of which applications are incorporated herein by reference in their entirety for all purposes.

The possibility of integrating billions of transistors in silicon and the application of sophisticated back-end digital processing integrated with a mm-wave front-end, all integrated in a single die, can be leveraged to make robust, low-cost, high-yield fully integrated systems at mm-wave frequencies. Applications such as gigabit/s point-to-point links, wireless local area networks (WLANs) with extraordinary capacity, short-range high data-rate wireless personal area networks (WPANs), vehicular radar, imaging sensors in planetary remote sensing, medical imaging, all-weather vision, plasma diagnostics and other commercial and defense applications with unprecedented levels of integration are no longer a distant possibility.

### Problems in Manufacturing High Frequency Integrated Circuits

As process technologies scale towards the sub-90 nm regime, transistors are being pushed towards their fundamental limits and model, parasitic, and process variations all contribute to a severe degradation in system performance. Device models provided by the standard foundries are generally not validated at mm-wave frequencies or thought to be practical, as related economic costs are high and the performance margin in mm-wave design is very small. For example, a 30 fF (femto Farad) parasitic capacitance, having a reactance of 56 ohms (X_{C}) at 94 GHz, can completely detune a matching network unless the smallest parasitic is accurately modeled and accounted for.

Integrating large numbers of transistors (e.g. billions of transistors) in silicon by use of existing process technologies remains problematic because of low manufacturing yields and very high economic costs of design and manufacture. At the limits of conventional CMOS processes, a design that relies on the accuracy of device and passive modeling is generally followed up with fabrication of test structures, custom active device modeling and several iterative runs (with the associated added expense), all of which, due to process variations, nevertheless fail to guarantee an optimum performance. Production of such designs is generally reduced to unacceptably low yield percentages and such designs are thought to be not commercially viable for large volume production.

One convention solution to the problem of low production yield caused by process variation is to design conservatively and to attempt to guarantee performance at all corners of a performance envelope (e.g., to meet stringent military requirements) or to use an architecture that is inherently less prone to parasitics (e.g., a wideband design). However, such workarounds generally come with a cost of higher power or a larger chip area or one needs to sacrifice transistor performance resulting in a suboptimum performance. Furthermore, such workarounds completely overlook the fundamental advantages of CMOS integration which comes with almost limitless computational abilities in the digital domain and where transistors are so inexpensive that, relative to the related design and manufacturing costs, they are virtually free.

### Self-Healing High Frequency Integrated Circuits

We describe hereinbelow a new concept of self-healing or self-adjusting autonomic systems, with an emphasis on mm-wave CMOS circuits, such as, for example, a mm-wave CMOS power amplifier. Our self-healing techniques are used to mitigate the effects of process variations, model inaccuracies and aging and environmental effects on circuits. Self-healing techniques can be accomplished, by automatic monitoring and sensing and subsequent on-chip corrections and adjustments such as by use of tunable active and passive elements, tuned via a self-sustained control and optimization process using a general purpose programmable computer programmed with a set of instructions recorded on a computer-readable medium. In some embodiments, an application-specific integrated circuit (ASIC), a dedicated logic circuit, or a number of standard “cells” that can perform the necessary computational operations can be used in place of a general purpose programmable computer in order to save chip area (or chip “real estate”) and/or to save expense and effort. We believe that such a self-healing approach can reliably overcome the fundamental shortcomings of variability and uncertainty in highly-scaled technology nodes, without a sacrifice in performance. It is contemplated that such self-healing techniques can increase first-pass functional production yields to 75-90% which is expected to make application of CMOS processes viable for fabricating devices suitable for commercial mm-wave applications.

Integrated CMOS mm-Wave Power Amplifier

A mm-wave power amplifier is one of the most challenging blocks to integrate in CMOS. The size of integrated transistors generally decreases with advances in integrated processes. Thus, with each advance in integrated processes, transistor operating voltages are falling with decreased transistor sizes. Power is proportional to voltage squared. Because the power available scales quadratically with the supply voltage, the power available from each transistor (e.g., each MOS transistor of a CMOS integrated circuit) reduces dramatically with voltage. Therefore, as we push frequency of operation of transistors further and further towards their fₘₐₓ, in some embodiments, we combine the output power of several transistors to achieve desired power levels. In addition, in some embodiments, we can combine the output power of several stages (either on-chip or off-chip) through electromagnetic radiation via on-chip antennas. On-chip antennas, as well as other types of power combiners, have ohmic losses due to skin effect. In addition, combining an increasing number of output stages implies a higher impedance transformation ratio (assuming antenna impedance does not change significantly) which decreases the bandwidth and therefore the margin of error in a matching network. Slight detuning due to node parasitics, process variation or model inaccuracies can cause a severe degradation in output power, efficiency and gain. Such degradation in output power, efficiency and gain is unacceptable at mm-wave frequencies, where the power gain in bulk CMOS technology is limited.

W-Band mm-Wave Power Amplifier in CMOS

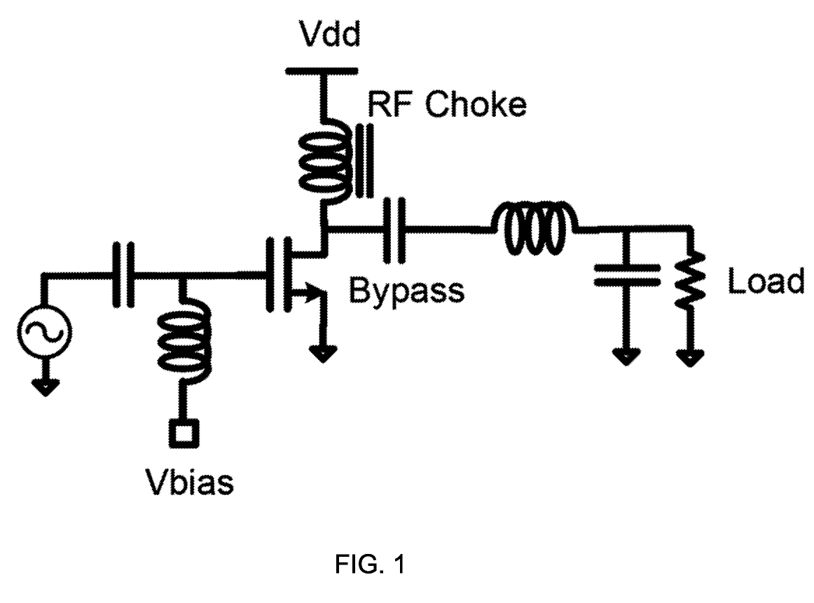

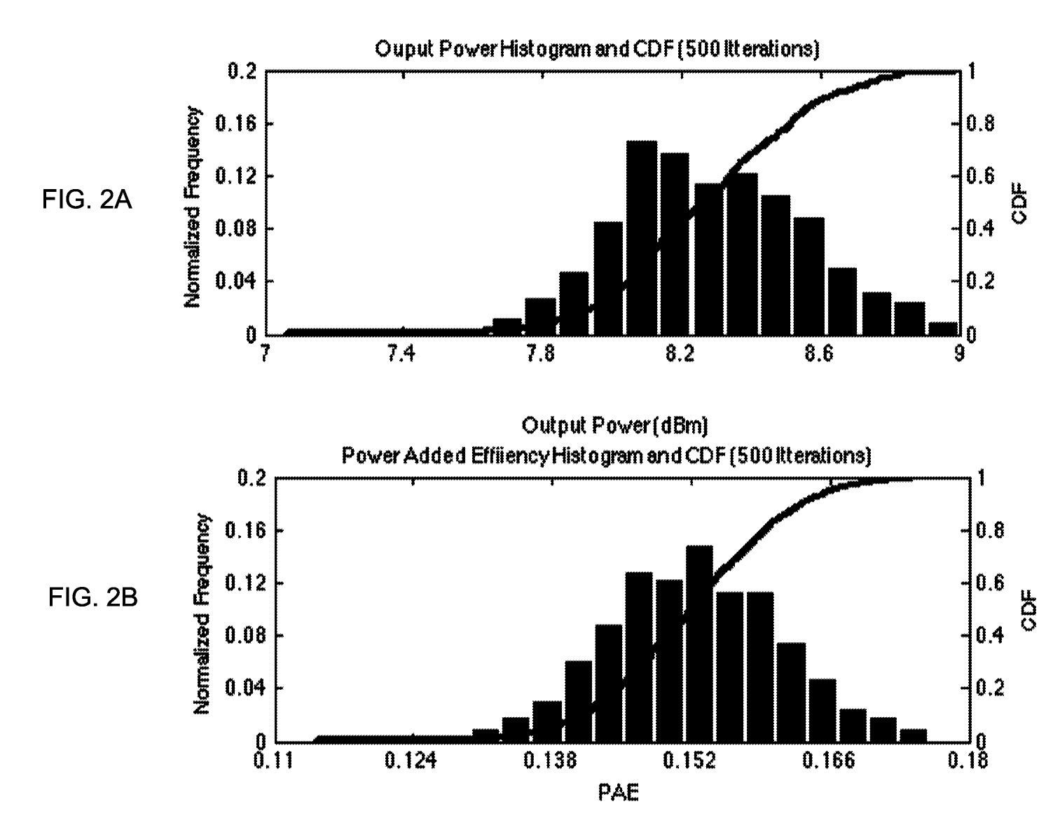

An exemplary W-band (e.g., 94 GHz) power amplifier in 32 nm or 45 nm bulk CMOS technology is now described in more detail. FIG. 1 shows a schematic diagram of a section of a power amplifier. The power amplifier of FIG. 1 was simulated as biased in Class AB. Inductors were simulated with quality factor of 10 at 94 GHz. As shown in FIG. 2A and FIG. 2B, a Monte Carlo simulation was run which shows wafer-to-wafer variation over a range of Output Power (dBm) (FIG. 2A) and over a range of Power Added Efficiency (PAE) (FIG. 2B), with both simulations performed for the circuit of FIG. 1. The Monte Carlo simulation for a process variation of a bulk 65 nm CMOS technology shows how output power, gain, and efficiency can be expected to vary from wafer to wafer. Both simulations assumed no passive variations and absolute model accuracy and were therefore expected to be optimistic.

The single stage power amplifier of FIG. 1 was biased in class AB and matched at 94 GHz. From process variations alone, the output power can vary by 1 dB and the PAE can have a deviation of 3%. When model inaccuracies of active and passive devices are further included, the variation is expected to be much higher. In the Monte Carlo simulation of FIG. 2, nearly 70% of the yield fails to provide the designed 8.5 dB power level.

With a typical available input power of 5 dBm, current state of the art designs work around problems of process variation by embedding several capacitors in matching networks which are either digitally switched on and off as needed through manual control or are adjusted by laser trimming to bring the center frequency to the desired value. However, to our knowledge, there has been no concerted effort to automate the process and/or to mitigate losses, such as when the amplifier is forced to work under high VSWR conditions. Furthermore, under high VSWR conditions, the power amplifier can oscillate due to poor reverse isolation at high frequencies.

Another problem related to power amplifiers is the reduction of efficiency during “backoff” (gain non-linearity at higher operating power levels). Since the peak efficiency (at higher power levels) is lower than is achieved for low RF levels, backoff reduces the performance of mm-wave power amplifiers.

### Self-Healing: A New Design Philosophy

As described hereinabove, CMOS processes such as digital CMOS processes have generally been thought to be impractical for high frequency circuits, and especially unsuitable for mm-wave applications. However, we have found that such CMOS processes can be used for high frequency RF circuits, including circuits used at mm-wave frequencies, by use of a careful amalgamation of the fundamental design procedures of analog and microwave circuit design. Our techniques include a careful modeling of both devices and high-frequency passive components. We have been able to mitigate these challenges by evaluation and critique of existing techniques and innovations in passive design, efficient power extraction and power combining. We now describe the techniques of self-healing (described hereinbelow in detail) as a holistic solution which attempts to substantially overcome all the fundamental problems of integrated circuit variation at a new level of abstraction. Instead of identifying and confronting individual problems and then devising custom solutions for each of them, self-healing constitutes a general design philosophy which allows an integrated circuit to achieve optimum performance over a range of both process variations as well as variation related to environmental factors.

### Sensing

To develop the methodology of self-healing, we begin with an identification of relevant performance parameters that can be either directly or indirectly sensed. Self-actuation (in some embodiments, a fully automatic control aspect of the self-healing technique), can then be implemented through a control process operating on a general purpose programmable computer programmed with a set of instructions recorded on a computer-readable medium based on these performance metrics. Specifically with regard to the exemplary power amplifier, the relevant performance parameters include output power, efficiency, gain, and linearity. Therefore, a self-healing mm-wave power amplifier would typically include reliable, low-power, low-area, high impedance and/or low-insertion loss mm-wave sensors that can monitor metrics (e.g., output power, efficiency, gain, and linearity) of the power-amplifier through direct evaluation and/or through sensing other variables which have a known relationship with output power, efficiency, gain, and/or linearity.

### Sensing Power

One way to directly sense (measure) input and output power is with a high impedance Schottky peak detector. Since the cut-off frequency of typical Schottky diodes in 32 nm typically exceeds 1 THz, these diodes are suitable for use as low-area, low power sensors for mm-wave power detection. High frequency power detection and implementation in standard CMOS processes based on high impedance Schottky peak detectors has been previously demonstrated.

### Exemplary Self-Healing Architecture

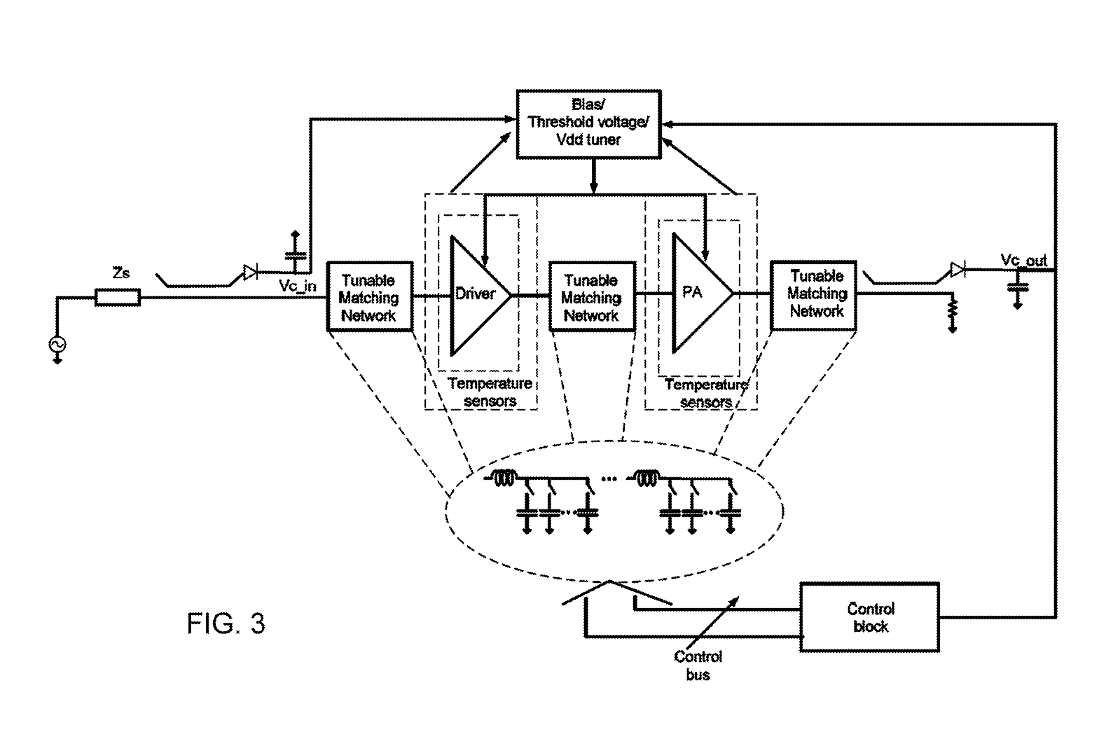

FIG. 3 shows a block diagram of a simplified architectural overview of various sensing and actuating mechanisms for an exemplary two stage power amplifier. The self-healing scheme uses the sensors and actuators shown around a core power amplifier. For power sensing, the output power can be coupled to the diode detector using an on-chip coupler or directly passed through it, depending on the loading effects of the diode. The coupler can also be designed to couple minimal power above some sensing threshold used for sensing. The effect of loading of the sensor on the output power network can be automatically adjusted as a part of the self-healing process through adjustments of an output tuning network as described herein below in more detail.

### Gain, PAE, and Drain Efficiency Sensing

PAE is defined by the following equation:

$$PAE = \frac{Output Power - Input Power}{Pdc} \qquad Eqn . 1$$

As seen in Eqn. 1, to estimate drain efficiency or PAE, the DC power (P_{dc}) consumed is measured. One direct way to measure the DC power consumed is by sensing the power supply current by passing it through a transistor and mirroring it. While this DC power sensing can be done for a cascade stage, for a common source stage, the higher supply voltage typically used can degrade efficiency. One contemplated alternative approach is to mirror a scaled version current through the PA by use of a voltage source below ground. It is also contemplated that there are other methods suitable for efficient bias current detection.

Circuit parameters can also be measured indirectly, such as by sensing their effects on other metrics, which in some cases are easier to measure. There are also variables in the nonelectrical domain which are indicative of PA efficiency. For example, lower efficiency implies a high power dissipation in active and/or passive circuit devices, which raises the local temperature surrounding the core. Therefore, the temperature of the core or parts of the circuit can be measured, for example, by use of well-known proportional to absolute temperature (PTAT) sensors. PTAT temperature sensors can be built on-chip to monitor heat dissipation and therefore to estimate efficiency inferred from the temperature measurements. One challenge is the calibration of the PTAT circuitry over ambient temperature. However, ambient temperature can also be sensed. PTAT can provide a reliable, low-cost and low-power method for sensing efficiency.

Techniques such as polar loop and Cartesian feedback, which have been demonstrated for low RF frequencies, as well as other suitable approaches, are contemplated for improving linearity. Information regarding gain of the PA can be obtained from the outputs of peak detectors realized, for example, with Schottky diodes.

Information about accuracy of matching networks (e.g., matching network tuning) can also be determined by sensing the phase difference between gate and drain voltage of the amplifier. For example, at nearly perfect load-pull matching, the gate and drain voltage will be completely out of phase. However, due to the presence of gate resistance, this phase relationship may not be satisfied and in general, it is less feasible to tap the voltage across the MOS gate capacitor. An alternative contemplated method is to sense the phase difference between the gate current and drain voltage which should be at quadrature phase. It is also believed that vector sensors can be extended to other parts of self-healing systems (e.g., transceivers) for measuring I/Q imbalance and other parameters.

### Actuators

Information obtained from the various sensing mechanisms can be processed through an optimization and control process operating on a general purpose programmable computer programmed with a set of instructions recorded on a computer-readable medium. The optimization and control process can activate the various passive and active actuation mechanisms which regulate the circuitry to optimize performance and which can perform self-healing as needed. Generally, a transistor is coupled into a circuit or decoupled by operation of the transistor (e.g., operation of a transistor gate) to place the transistor in or out of the circuit or to cause some related device (e.g., an impedance element or impedance tuning structure of a tuned network) to be placed in or out of a circuit, to affect operation of an actuator.

Some exemplary actuating mechanisms are shown in FIG. 3. For example, the tunable network can be a multistage LC ladder network where individual and/or groups of capacitors in the capacitor banks can be switched on and off for tuning. Any suitable matching network can be used. Typically multi-stage LC matching networks can be used to achieve a desired quality factor. The matching networks can be tuned, for example, by using switched capacitors via an autonomous control process operating on a general purpose programmable computer programmed with a set of instructions recorded on a computer-readable medium which aims, for example, to maximize output power for a given bias and input power condition. The autonomous control process can be a control process as simple as a gradient descent process, or the autonomous control process can include more complex optimization routines. The flexibility of tuning over a large portion of a Smith chart can also enable a dynamic adjustment of the output matching network, for example, during a backoff condition, to increase efficiency.

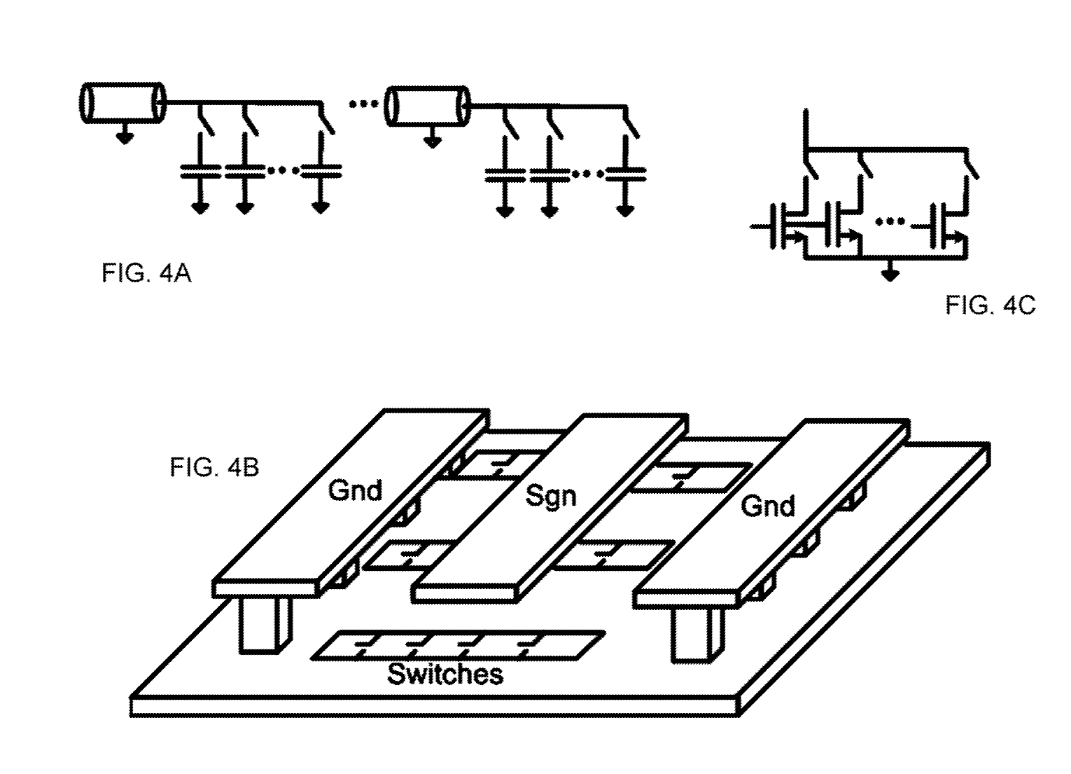

Tunable matching networks can also be realized with transmission lines instead of inductors as shown in FIG. 4A. Slow-wave transmission lines whose slots can be digitally controlled to switch on and off to allow flow of return current as shown in FIG. 4B are also believed to be suitable for use in tunable networks. In slow-wave transmission lines, dynamic changing of the return current flow allows control of characteristic impedance and wave velocity and can also be used for tunable matching. It is also contemplated that further analysis of optimum matching networks will identify other suitable matching networks and other types of actuating mechanisms that can extend useful bandwidth with minimum loss and to control overhead.

Any suitable active devices can be used to control the actuating mechanisms (e.g., one or more tunable matching networks of a power amplifier) and to allow re-configurability. Such active devices can be added in parallel to the core through logic control as shown in FIG. 4C. Active selection of multiple actuating mechanisms can be useful during backoff, for example, to save DC power and also to provide coarse tuning for optimum efficiency and/or optimum output power output, such as for a given input power. The incremental adjustments provided by such active devices can be sized in a weighted fashion (e.g., binary weighted) to allow for a relatively fine adjustment. Such incremental adjustments can be related to device sizes. The bias voltage and the threshold voltage through body effect (triple-well process) can be adjusted based on a gain estimate gathered from the output of peak detectors. Temperature sensors can also communicate with the control block (HG. 3) to provide information on the efficiency of the power amplifier.

The control block of FIG. 3 can adjust, for example, the supply, bias and/or the threshold voltage to optimize performance. Such a control block can include, for example a state-machine in digital logic, software, or any combination thereof. It is contemplated that the “control” and “Bias/Threshold voltage/V_{dd} tuner” blocks of FIG. 3 can be further controlled by a suitable “parent” control process operating on a general purpose programmable computer programmed with a set of instructions recorded on a computer-readable medium. It is contemplated that switches having a suitable wideband as well as a sufficient high off-state isolation and low insertion loss at on-state for use at mm-wave frequencies can be fabricated in CMOS.

### Self-Healing PA (Power Amplifier)

We now summarize some of the self-healing techniques described hereinabove by describing a self-healing PA. In order to heal, the state of the PA is assessed. Some exemplary relevant metrics (sensed parameters for assessing the state of the PA) include, center frequency, PAE, Output Power, Bandwidth, and gain. These metrics can be calculated knowing the input and output power at various frequencies. For example, detection of the output power can be done with an envelope detector with a diode and a low pass filter, to provide a maximum voltage which gives an estimate of output power. The accuracy of the output power estimate relies on how accurately the load impedance is known, which can also be subject to process variations, depending on what the load is and if the load is on-chip or off-chip. Measuring input power can be somewhat more difficult because the load on the input is the gate of the transistor, so process variation, for example, can change the input power for a given measured peak voltage. If the goal is to know the absolute metrics as outlined above, such errors can be problematic. However, if the goal is to maximize or optimize those metrics, knowledge of the absolute value of a given parameter is less important than how that parameter changes during a particular self-healing operation (e.g., tuning). Similarly, the final 50 ohm load at the output might not be exactly 50 ohms. However, the load characteristics (e.g. load impedance, such as for example, the load impedance of an antenna) generally do not change significantly during tuning, so the output power, relative to other tuning levels, can be known. The same should be true for the input power. In addition, the gate impedance does not change very much as the matching networks are tuned, so relative input power could also be found during the time period of self-healing tuning.

Turning now to PA actuators, one exemplary method for tuning the PA is to use a varactor diode to tune a matching network. In other embodiments, at relatively high frequencies, transmission line matching networks can be preferred over varactor diodes. To tune a transmission line, the length and/or the impedance can be tuned. To tune the length of a shorted stub in a matching network, switches can be used to short a part of the line to ground. It is also believed that in some embodiments, adjustable slotted ground planes on the transmission lines can be used for tuning. If the slots have switches across them, by varying how many of the slots are open, a transmission line can be adjusted from a normal non-slotted line to a fully slotted slow wave line. The load itself can also be varied. In the case of the direct antenna modulation (DAM), which has been described, such as for example, in Babakhani, et. al, Transmitter Architectures Based on Near-Field Direct Antenna Modulation, IEEE Journal of Solid-State Circuits, vol. 43, no. 12, pages 2674-2692, December 2008, switching combinations can be chosen such that the amplifier always sees a 50 ohm antenna. However, other combinations with different impedances can also be used to help better tune the PA. With suitable detection methods, DAM also allows for tuning out the impact of the environment on the load impedance seen be the PA. For example, the self-healing technique can be used to set a switching combination to match into a nominal 50 ohm load, which has been shifted to some other load impedance by, for example, the presence of a nearby object. In addition, the bias voltage on the gate and the bias voltage on the drain can be adjusted to change the gain and set the operation point of the amplifier.

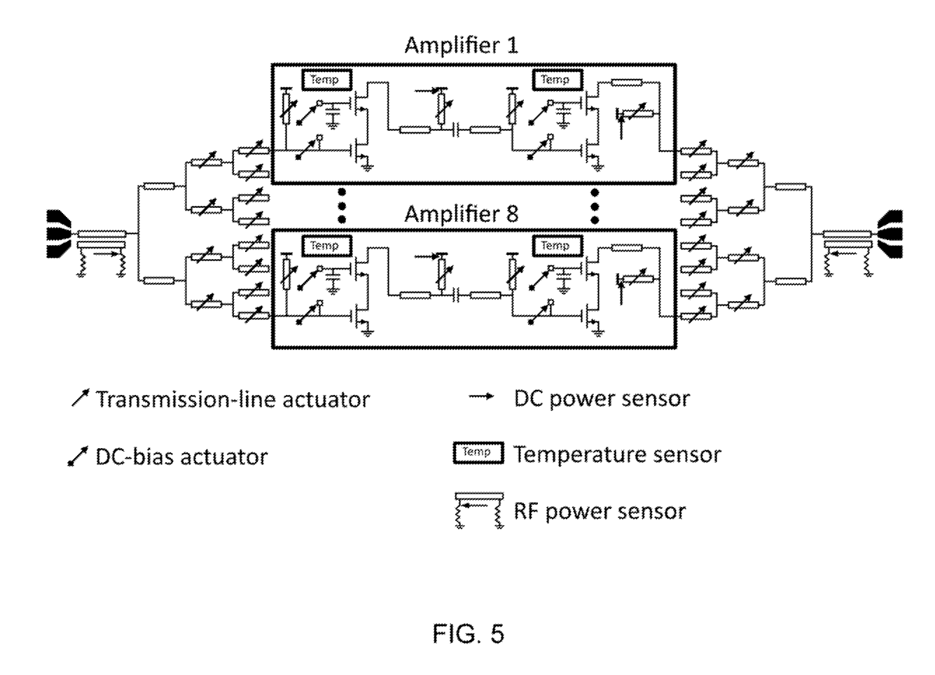

FIG. 5 shows a block diagram of one exemplary embodiment of a self healing power amplifier having eight parallel amplifier stages. An input signal is divided by a plurality of transmission-line actuators (e.g. tunable transmission lines as discussed hereinabove) to feed the eight parallel amplifier sections. DC-bias actuators are also shown in each of the eight amplifier stages. The outputs of the eight amplifier sections are combined into a single power output using transmission-line actuators. Exemplary sensors (suitable for measurement of relevant performance metrics, as described in detail hereinabove) include temperature sensors and power sensors.

Recording the results from an operation or data acquisition, such as for example, recording performance metrics is understood to mean and is defined herein as writing output data to a storage element, to a machine-readable storage medium, or to a storage device. Machine-readable storage media that can be used in the invention include electronic, magnetic and/or optical storage media, such as magnetic floppy disks and hard disks; a DVD drive, a CD drive that in some embodiments can employ DVD disks, any of CD-ROM disks (i.e., read-only optical storage disks), CD-R disks (i.e., write-once, read-many optical storage disks), and CD-RW disks (i.e., rewriteable optical storage disks); and electronic storage media, such as RAM, ROM, EPROM, EEPROM, Compact Flash cards, PCMCIA cards, ExpressCard cards, solid state drives (SSD) or alternatively SD or SDIO memory; and the electronic components (e.g., floppy disk drive, DVD drive, CD/CD-R/CD-RW drive, or Compact Flash/PCMCIA/ExpressCard/SD adapter) that accommodate and read from and/or write to the storage media. As is known to those of skill in the machine-readable storage media arts, new media and formats for data storage are continually being devised, and any convenient, commercially available storage medium and corresponding read/write device that may become available in the future is likely to be appropriate for use, especially if it provides any of a greater storage capacity, a higher access speed, a smaller size, and a lower cost per bit of stored information. Recording data for later use (e.g., writing data to memory or to digital memory) can be performed to enable the use of the recorded information as output, as data for display to a user, or as data to be made available for later use. Such digital memory elements or chips can be standalone memory devices, or can be incorporated within a device of interest. “Writing data” or “writing data to memory” is defined herein as including writing transformed data to registers within a microcomputer.

“Microcomputer” is defined herein as synonymous with microprocessor, microcontroller, and digital signal processor (“DSP”). It is understood that memory used by the microcomputer, including for example instructions for data processing coded as “firmware” can reside in memory physically inside of a microcomputer chip or in memory external to the microcomputer or in a combination of internal and external memory. Similarly, analog signals can be digitized by a standalone analog to digital converter (“ADC”) or one or more ADCs or multiplexed ADC channels can reside within a microcomputer package. It is also understood that field programmable array (“FPGA”) chips, application specific integrated circuits (“ASIC”) chips, and other specifically configured and tasked digital integrated circuits and sections of integrated circuits (e.g., sections, such as digital sections of integrated CMOS circuits) can perform microcomputer functions, either in hardware logic, software emulation of a microcomputer, or by a combination of the two. Apparatus having any of the inventive features described herein can operate entirely on one microcomputer or can include more than one microcomputer.

General purpose programmable computers useful for controlling instrumentation, recording signals and analyzing signals or data according to the present description can be any of a personal computer (PC), a microprocessor based computer, a portable computer, or other type of processing device. The general purpose programmable computer typically comprises a central processing unit, a storage or memory unit that can record and read information and programs using machine-readable storage media, a communication terminal such as a wired communication device or a wireless communication device, an output device such as a display terminal, and an input device such as a keyboard. A display terminal can be a touch screen display, in which case it can function as both a display device and an input device. Different and/or additional input devices can be present such as a pointing device, such as a mouse or a joystick, and different or additional output devices can be present such as an enunciator, for example a speaker, a second display, or a printer. The computer can run any one of a variety of operating systems, such as for example, any one of several versions of Windows, or of MacOS, or of UNIX, or of Linux. Computational results obtained in the operation of the general purpose computer can be stored for later use, and/or can be displayed to a user. At the very least, each microprocessor-based general purpose computer has registers that store the results of each computational step within the microprocessor, which results are then commonly stored in cache memory for later use.

Many functions of electrical and electronic apparatus can be implemented in hardware (for example, hard-wired logic), in software (for example, logic encoded in a program operating on a general purpose processor), and in firmware (for example, logic encoded in a non-volatile memory that is invoked for operation on a processor as required). The present invention contemplates the substitution of one implementation of hardware, firmware and software for another implementation of the equivalent functionality using a different one of hardware, firmware and software. To the extent that an implementation can be represented mathematically by a transfer function, that is, a specified response is generated at an output terminal for a specific excitation applied to an input terminal of a “black box” exhibiting the transfer function, any implementation of the transfer function, including any combination of hardware, firmware and software implementations of portions or segments of the transfer function, is contemplated herein, so long as at least some of the implementation is performed in hardware.

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A self-healing monolithic integrated circuit comprising:
an electronic circuit having a plurality of transistors, said electronic circuit disposed between and electrically coupled to at least one input terminal and at least one output terminal;
at least one sensor disposed within and electrically coupled to said electronic circuit and configured to sense a performance metric of said electronic circuit;
a plurality of actuators disposed within said circuit, each actuator of said plurality of actuators having electrically coupled to it a control terminal, said plurality of actuators is configured to perform a selected one of, electrically coupling at least one transistor of said plurality of transistors into said electronic circuit and electrically de-coupling at least one transistor of said plurality of transistors, in response to operation of one of said control terminals to improve said performance metric; and
at least one power terminal and at least one common terminal electrically coupled to said electronic circuit and configured to accept power to operate said self-healing monolithic integrated circuit.

2. The self-healing monolithic integrated circuit of claim 1, wherein said self-healing monolithic integrated circuit comprises CMOS technology.

3. The self-healing monolithic integrated circuit of claim 1, wherein said performance metric comprises a performance metric selected from the group consisting of output power, efficiency, gain, PAE, and linearity.

4. The self-healing monolithic integrated circuit of claim 1, wherein said self-healing monolithic integrated circuit is component of a system selected from the group of systems consisting of a point-to-point link, a local area network (LAN), a personal area network (PAN), a vehicle radar system, an all weather vision system, a medical imaging sensor, a space probe imaging system, and a plasma diagnostic system.

5. The self-healing monolithic integrated circuit of claim 1, further comprising a general purpose programmable computer and a set of instructions recorded on a computer-readable medium which when operating on said general purpose programmable computer cause said general purpose programmable computer to be configured to receive sensed information and to set at least one of said control terminals to optimize said performance metric.

6. The self-healing monolithic integrated circuit of claim 5, wherein said set of instructions recorded on a computer-readable medium when operating runs on a computer device external to said monolithic integrated circuit.

7. The self-healing monolithic integrated circuit of claim 5, wherein said set of instructions recorded on a computer-readable medium when operating runs on a digital circuit disposed within said monolithic integrated circuit.

8. The self-healing monolithic integrated circuit of claim 7, wherein said digital circuit comprises a state machine.

9. The self-healing monolithic integrated circuit of claim 7, wherein said state machine is further controlled by a parent set of instructions recorded on a computer-readable medium.

10. The self-healing monolithic integrated circuit of claim 1, wherein said actuator comprises a tunable matching network.

11. The self-healing monolithic integrated circuit of claim 10, wherein said tunable matching network comprises a selected one of a T-line and a tunable slow-wave transmission line.

12. The self-healing monolithic integrated circuit of claim 10, wherein said self-healing monolithic integrated circuit is configured to automatically self-heal in response a selected one of change in antenna impedance and load characteristics.

13. The self-healing monolithic integrated circuit of claim 1, wherein said circuit comprises a mm-wave circuit.

14. The self-healing monolithic integrated circuit of claim 1, wherein said self-healing monolithic integrated circuit senses a phase difference between a gate current and a drain voltage.

15. The self-healing monolithic integrated circuit of claim 14, wherein said self-healing monolithic integrated circuit is configured to operate at least one of said control terminals to cause said phase difference between said gate current and said drain voltage to change towards a quadrature phase difference.

16. The self-healing monolithic integrated circuit of claim 1, wherein said self-healing monolithic integrated circuit is configured to adjust a bias voltage or a threshold voltage through body effect (triple-well process) based on a gain estimate based on an output of a peak detector sensor.

17. The self-healing monolithic integrated circuit of claim 1, wherein said self-healing monolithic integrated circuit comprises a Schottky peak detector.

18. The self-healing monolithic integrated circuit of claim 1, wherein said self-healing monolithic integrated circuit senses an efficiency metric of said circuit using a temperature sensor.

19. The self-healing monolithic integrated circuit of claim 18, wherein said temperature sensor comprises a PTAT sensor.

20. The self-healing monolithic integrated circuit of claim 1, further comprising two or more on-chip antennas configured to provide power combining.
